(19) United States
(12) Patent Application Publication
(10) Pub. No.: US 2013/0214370 A1
(43) Pub. Date: Aug. 22, 2013

(54) SYSTEM AND METHOD FOR MINIMIZING DEFLECTION OF A MEMBRANCE OF AN ABSOLUTE PRESSURE SENSOR

(71) Applicants: Javed Hussain, Cupertino, CA (US); Mohammad Yunus, Castro Valley, CA (US); James T. Suminto, West Covina, CA (US)

(72) Inventors: Javed Hussain, Cupertino, CA (US); Mohammad Yunus, Castro Valley, CA (US); James T. Suminto, West Covina, CA (US)

(73) Assignee: S3C, Inc., Sunnyvale, CA (US)

(21) Appl. No.: 13/695,972

(22) PCT Filed: May 3, 2011
(86) PCT No.: PCT/US11/35062

§ 371 Date: Dec. 6, 2012

Related U.S. Application Data
(60) Provisional application No. 61/330,767, filed on May 3, 2010.

(51) Int. Cl. B81B 7/00

(52) U.S. Cl. CPC B81B 7/0058
USPC 257/420

(57) ABSTRACT

A Micro-Electro-Mechanical System (MEMS) pressure sensor is disclosed, comprising a gauge wafer, comprising a micromachined structure comprising a membrane region and a pedestal region, wherein a first surface of the micromachined structure is configured to be exposed to a pressure medium that exerts a pressure resulting in a deflection of the membrane region. The gauge wafer also comprises a plurality of sensing elements patterned on the electrical insulation layer on a second surface in the membrane region, wherein a thermal expansion coefficient of the material of the sensing elements substantially matches with a thermal expansion coefficient of the material of the gauge wafer. The pressure sensor comprises a cap wafer coupled to the gauge wafer, which includes a recess on an inner surface of the cap wafer facing the gauge wafer that defines a sealed reference cavity that encloses and prevents exposure of the sensing elements to an external environment.

### CROSS-REFERENCE TO RELATED APPLICATIONS

This application claims the benefit of U.S. Provisional Application No. 61/330,767, filed May 3, 2010, entitled “TECHNIQUE TO STOP THE MAXIMUM DEFLECTION OF THE MEMBRANE IN THE PIEZO RESISTIVE ABSOLUTE PRESSURE SENSOR MEMS WHEN PRESSURE APPLIED TO PREVENT THE DAMAGE TO MEMBRANE AND A TECHNIQUE THAT REDUCES OR ELIMINATES CHIPPING FROM THE EFFECTS OF DICING DIE THAT HAVE METALLIZATION COATINGS APPLIED TO THE BACKSIDE OF WAFER LEVEL DEVICES”, and is a continuation-in-part of U.S. patent application Ser. No. 12/397,253, filed Mar. 3, 2009, entitled, “Media-Compatible Electrically Isolated Pressure Sensor for High Temperature Applications”, all of which are incorporated herein by reference in their entireties.

### FIELD OF THE INVENTION

The present invention relates generally to pressure sensing, and more specifically to pressure sensing in a harsh and/or electrically conducting pressure medium at high temperature.

### BACKGROUND

Membrane-based pressure sensors have been used for a variety of applications, where pressure exerted by a pressure medium deflects a membrane, and sensing elements (such as strain gauges) coupled to the membrane sense the deflection and help correlate the deflection with the amount of pressure.

There are two major kind of pressure sensors. The first one is called gauge pressure sensor, which measures pressure with respect to the atmospheric pressure. The other is called absolute pressure sensor which typically measures pressure with respect to a vacuum or zero pressure.

FIGS. 1A and 1B respectively show a conventional gauge pressure sensor 100 and a conventional absolute pressure sensor 110, both by Silicon Microstructures, Inc. of Milpitas, Calif. (pressure sensor models SM5102). Both the pressure sensors 100 and 110 use a silicon micromachined structure (also known as a gauge wafer) with a membrane having sensing elements (not shown) on the top or outer surface. The micromachined structure is mounted on a support structure (also known as a spacer). Typical dimensions of the pressure sensors are shown in millimeters. Both the pressure sensors 100 and 110 are top side pressure sensors, i.e. the top or outer side of the membrane is exposed to the pressure medium. The support structure in the gauge pressure sensor 100 has an opening to expose the opposite side (i.e. the bottom side or the inner side) of the membrane to atmospheric pressure. On the other hand, the support structure in the absolute pressure sensor 110 has no opening, and defines a vacuum reference cavity underneath the membrane. Both the pressure sensors 100 and 110 are not ideal for applications involving harsh pressure media, as the sensing elements on the top side of the membrane may come in contact with the harsh pressure medium if a protective coating on the sensing elements is damaged.

The gauge pressure sensor reads pressure with respect to atmospheric pressure. Atmospheric pressure varies over elevation and weather conditions. Thus, absolute pressure sensor is preferred where high accuracy is needed. For example, gauge pressure reading can change by 2-3 psi due to variation in atmospheric pressure. Thus, it can contribute to 2% to 3% error in the pressure reading if the full scale is 100 psi. Most of the new pressure sensor applications below 500 psi requires +/−1% accuracy over operational temperature range, pressure range, and over the life of the product. Thus absolute pressure sensing is becoming very important for such applications.

In a current design of the MEMS with cavity over the membrane for absolute pressure gauge, the membrane deflects as the pressure is applied. Since there is no way to control the deflection, the membrane breaks after certain pressure applied, making the part permanently damaged. There is nothing in the current process to stop the maximum deflection of the membrane.

Accordingly, what is desired is to provide a system and method that overcomes the above issues. The present invention addresses such a need.

### SUMMARY OF THE INVENTION

A Micro-Electro-Mechanical System (MEMS) pressure sensor is disclosed. The MEMS pressure sensor comprises a gauge wafer. The gauge wafer comprises a micromachined structure comprising a membrane region and a pedestal region, wherein a first surface of the micromachined structure is configured to be exposed to a pressure medium that exerts a pressure resulting in a deflection of the membrane region. The gauge wafer also comprises a plurality of sensing elements patterned on the electrical insulation layer on a second surface in the membrane region, wherein a thermal expansion coefficient of the material of the sensing elements substantially matches with a thermal expansion coefficient of the material of the gauge wafer.

Additionally, the pressure sensor comprises a cap wafer coupled to the gauge wafer, which includes a recess on an inner surface of the cap wafer facing the gauge wafer that defines a sealed reference cavity that encloses the sensing elements and prevents exposure of the sensing elements to an external environment. The cap wafer includes peripheral bond pads defined on the gauge wafer to bring out electrical connections from the sensing elements to outside the sealed reference cavity. The pressure sensor also includes a spacer wafer with a central aperture aligned to the membrane region, bonded to the pedestal region of the micromachined silicon structure. Finally, the pressure sensor includes an etch stopper deposited on top of the cap wafer over the membrane region to act as a stop for the membrane region to prevent the membrane region from deflecting beyond design specifications of the membrane region.

Other aspects and advantages of the present invention will become apparent from the following detailed description, taken in conjunction with the accompanying drawings, illustrating by way of example the principles of the invention.

### BRIEF DESCRIPTION OF THE DRAWINGS

FIGS. 1A and 1B respectively show a conventional gauge pressure sensor and a conventional absolute pressure sensor, both by Silicon Microstructures, Inc. of Milpitas, Calif. (pressure sensor models SM5102).

FIG. 2 shows an embodiment of pressure sensor.

FIG. 3 is a diagram of the deflection of the membrane.

FIG. 4 shows an embodiment of pressure sensor in accordance with the present invention.

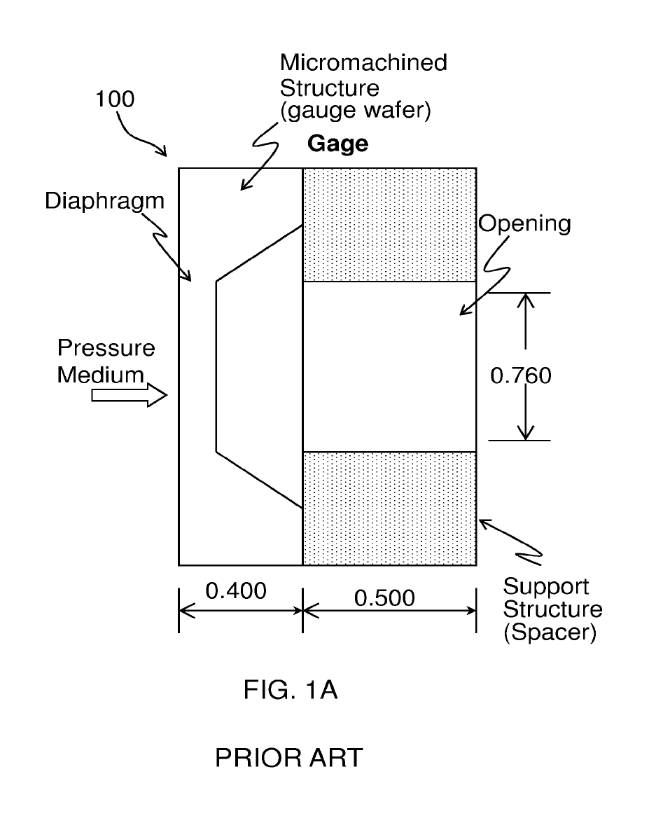

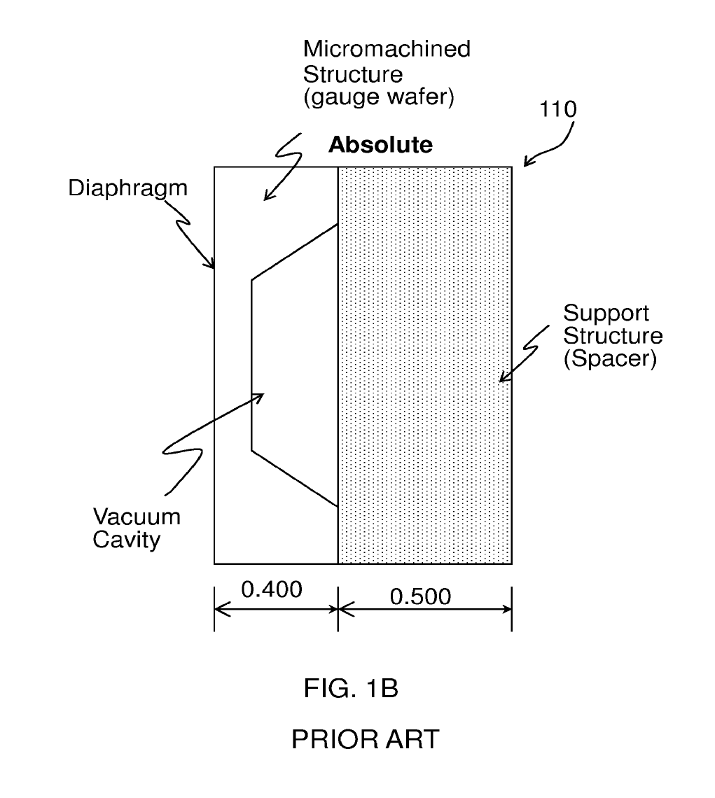

### DETAILED DESCRIPTION OF PREFERRED EMBODIMENTS

The present invention relates to a process technique to create a non-conductive stopper over the membrane to limit the deflection and to prevent the damage to membrane. The following description is presented to enable one of ordinary skill in the art to make and use the invention and is provided in the context of a patent application and its requirements. Various modifications to the preferred embodiment and the generic principles and features described herein will be readily apparent to those skilled in the art. Thus, the present invention is not intended to be limited to the embodiment shown but is to be accorded the widest scope consistent with the principles and features described herein.

Reference will now be made in detail to implementations of the example embodiments as illustrated in the accompanying drawings. The same reference indicators will be used throughout the drawings and the following description to refer to the same or like items.

In accordance with this disclosure, the components and process steps described herein may be implemented using various types of semiconductor manufacturing equipment. It is understood that the phrase “an embodiment” encompasses more than one embodiment and is thus not limited to only one embodiment.

Embodiments of the present invention describe pressure sensors that can be used for a wide range of temperature and pressure, including automobile applications. Though absolute pressure sensors are described in details for illustrative purposes, persons skilled in the art will appreciate that similar processes may be used to make other type of pressure sensors, such as gauge pressure sensors. In case of an absolute pressure sensor, a reference cavity may be at actual vacuum or zero pressure, or filled with a chemically compatible fluid (gas or liquid) with a known reference pressure, that is calibrated to determine the absolute pressure.

Although silicon is often shown as the material of choice for making a micromachined gauge wafer including the membrane, and a cap wafer that creates a reference cavity on top of the membrane, the scope of the invention is not limited by the choice of material. Similarly, although a spacer is shown be made of silicon or Pyrex or other type of glasses or ceramics, and the invention is not limited by the choice of spacer material.

Persons skilled in the art will appreciate that embodiments of the present invention are likely to have better thermal performance if the material of the gauge wafer and the material of the sensing elements have substantially similar coefficients of thermal expansion.

A system and method in accordance with the present provides a technique that uses minimal process steps to place either a material (such as SiO₂ or Nitride) over a membrane an absolute pressure sensor on a cap wafer cavity to prevent the membrane from breaking due to deflection by applying pressure. To describe the features of the present invention in more detail refer now to following discussion in conjunction with the accompanying figures.

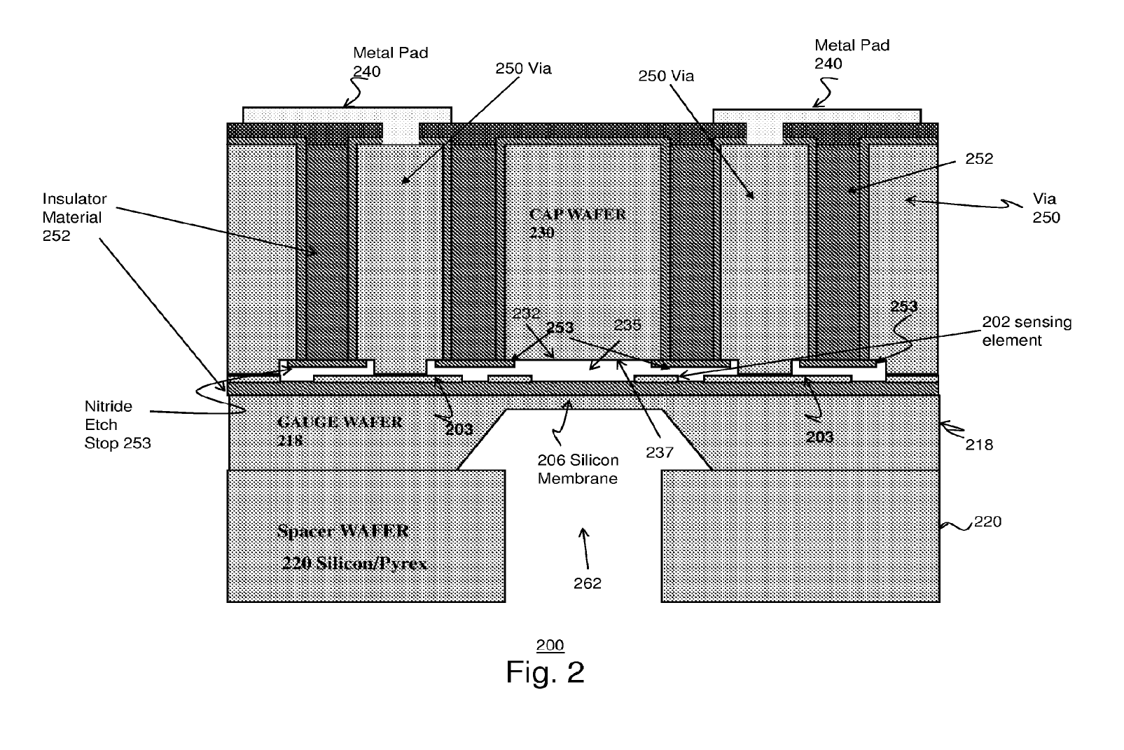

FIG. 2 shows an embodiment of pressure sensor 200 described in U.S. patent application Ser. No. 12/357,737 entitled “Media-Compatible Electrically Isolated Pressure Sensor for High Temperature Applications” and assigned to the assignee of the present application. Pressure sensor 200 comprises three main structural components: gauge wafer 218, cap wafer 230, and spacer wafer 220. Example dimensions for the thickness of the gauge wafer 218=0.4 mm, thickness of the spacer wafer 220=0.5 mm, thickness of the cap wafer 230=0.5 mm. Other dimensions, i.e. width of the gauge wafer 218, inner and outer diameters of the spacer wafer (220 respectively), width of the membrane region 206 etc. are also typically in the millimeter range. An example thickness of the thinned down silicon membrane is 27 micron. Other dimensions are possible depending on the materials and configurations.

Micromachined gauge wafer 218 may include silicon interconnectors 203. Interconnectors 203 are typically made of the same material as the sensing elements 202. In the embodiment shown in FIG. 2, fusion bonding is used to couple cap wafer 230 with gauge wafer 218. Other bonding techniques may be used and other interfacial layers may be employed according to the bonding technique. Sensing elements 202 may be exposed as shown in FIG. 2, or covered by a planarization/passivation layer (similar to layer 252). An external metal layer 260 (not shown) can be deposited at the bottom of membrane 206. For example, a Ti/Pt/Au 500 A/1000 A/1500 A metal layer can be deposited if spacer wafer 220 is blanket coated for bonding to a housing/package (not shown) that houses the pressure sensor 200. The housing may be made of Kovar or other materials, compatible to the pressure medium.

Cap wafer 230, when bonded to gauge wafer 218, creates reference cavity 235. Cap wafer 230 has a bottom surface 237 that includes a recess 232. The position and dimension of the recess 232 is such that it encloses sensing elements 202. Cap wafer 230 includes embedded vias 250 that are electrically conductive. Vias 250 may have insulating sidewalls (not shown) if the cap wafer is made of an electrically conducting material. In one embodiment, vias may be defined as portions of the conductive cap wafer 232 surrounded by insulating sidewalls. In other embodiments, cap wafer 230 may be an electrically insulating material, and vias are conductive pathways through the cap wafer. Electrical connectivity to sensing elements 202 are brought out through the vias 250 to an outer surface of the cap wafer 230. In one embodiment, outer surface of cap wafer 230 has an insulator layer (not shown) with windows defined in it to pattern metal pads 240. Metal pads 240 may be made of 1 um thick Al/Si/Cu or other interconnect or bonding metallization.

In the example shown in FIG. 2, material of the cap wafer 241 is silicon. Insulating sidewall 252 of each via 250 ensures that the vias are not shorted through the bulk silicon body of cap 230. When through-wafer silicon vias are used to bring out electrical connectivity from the vacuum cavity, cap wafer 230 uses silicon material with relatively low bulk resistivity. Other type of conductive materials can be used too for the cap wafer.

Spacer wafer 220 has a central hole 262 to give access to the pressure medium to the membrane. Hole 262 may be of any geometric shape, including circular, square, rectangular, polygonal etc.

In this embodiment, to make the absolute gauge pressure, silicon wafers are used to create bridge resistors over the thin membrane 206. The cap wafer 241 is then attached by fusion bonding to the gauge wafer 218, creating a cavity over the bridge resistors and membrane 206. When pressure is applied, the membrane 206 can deflect beyond its specified range and can rapture eventually, causing a permanent damage.

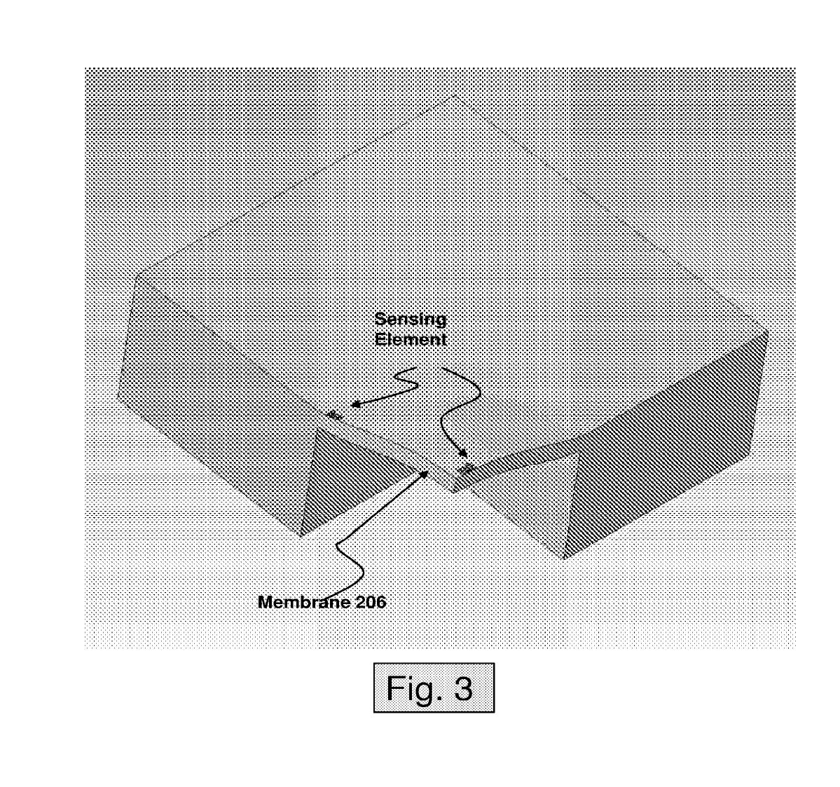

FIG. 3 is a diagram of the deflection of the membrane 206. In this embodiment, the membrane 206 deflects as the pressure is applied. Since there is no way to control the deflection, the membrane 206 breaks if a pressure is applied that exceeds the design specifications, permanently damaging the pressure sensor. There is nothing in the current process to stop the maximum deflection of the membrane 206.

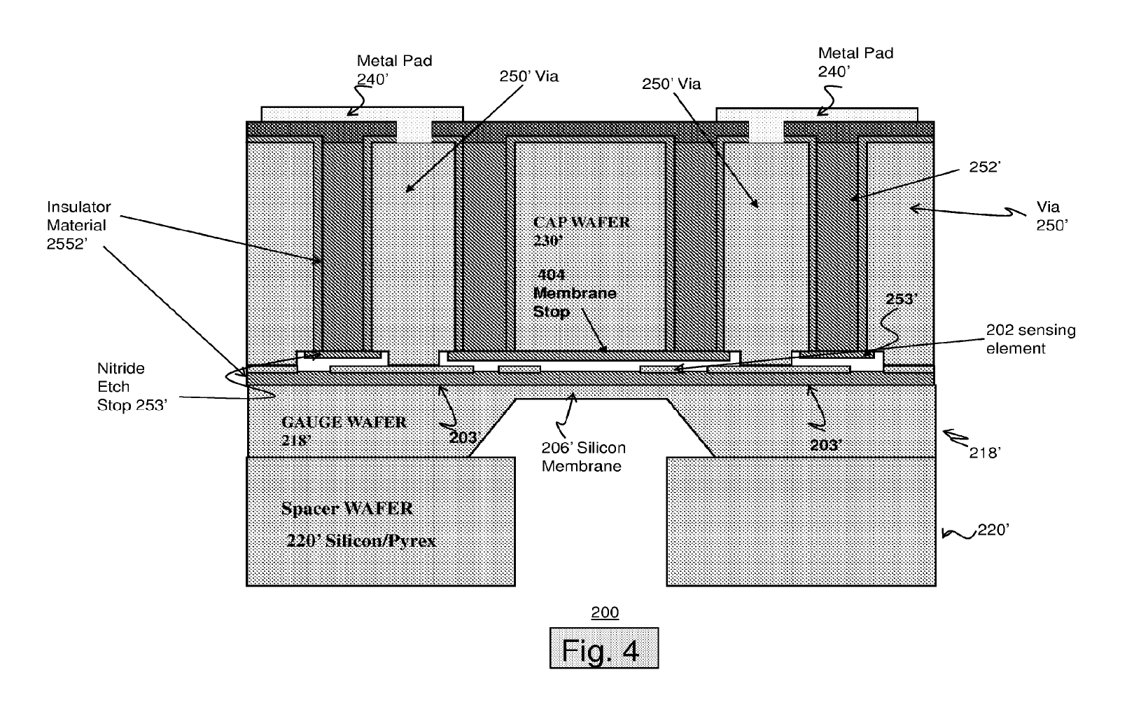

FIG. 4 shows an embodiment of pressure sensor 200 in accordance with the present invention. The absolute pressure sensor 200 shown in FIG. 4 has common elements to those shown in FIG. 2, which have similar designators. In a system and method in accordance with the present invention, a thick etch stopper 404, for example made from SiO₂ or Nitride is deposited on the cap wafer 241 over the membrane 206.

The etch stopper 204 is used for this purpose because the cap wafer 241 is highly doped to have low resistance to allow for contact with the bridge resistors. This deposited etch stopper 204 then acts as a stop for the membrane 206 and prevents it from deflecting beyond its designed specifications. With minimal process modification, the stopper 204 is placed over the membrane 206 which prevents the membrane from being damaged when maximum.

### CONCLUSION

A technique is devised to add non-conductive material over the membrane to act as a stopper to prevent the membrane to break when maximum pressure is applied. This prevents the part to damage permanently.

A SiO₂ or Nitride based stopper is used in the cavity over the bridge resistors to prevent the deflection of the membrane beyond its designed specifications, thus preventing to permanently damaging the membrane.

Although the present invention has been described in accordance with the embodiments shown, one of ordinary skill in the art will readily recognize that there could be variations to the embodiments and those variations would be within the spirit and scope of the present invention. Accordingly, many modifications may be made by one of ordinary skill in the art without departing from the spirit and scope of the appended claims.

What is claimed is:

1. A Micro-Electro-Mechanical System (MEMS) pressure sensor, comprising:
a gauge wafer, comprising:
a micromachined structure comprising a membrane region and a pedestal region, wherein a first surface of the micromachined structure is configured to be exposed to a pressure medium that exerts a pressure resulting in a deflection of the membrane region;
a plurality of sensing elements patterned on the electrical insulation layer on a second surface in the membrane region, wherein a thermal expansion coefficient of the material of the sensing elements substantially matches with a thermal expansion coefficient of the material of the gauge wafer;
a cap wafer coupled to the gauge wafer, comprising:
a recess on an inner surface of the cap wafer facing the gauge wafer that defines a sealed reference cavity that encloses the sensing elements and prevents exposure of the sensing elements to an external environment;
peripheral bond pads defined on the gauge wafer to bring out electrical connections from the sensing elements to outside the sealed reference cavity; and
a spacer wafer with a central aperture aligned to the membrane region, bonded to the pedestal region of the micromachined silicon structure; and
an etch stopper deposited on top of the cap wafer over the membrane region to act as a stop for the membrane region to prevent the membrane region from deflecting beyond design specifications of the membrane region.

2. The MEMS pressure sensor of claim 1, wherein the spacer wafer is made of Pyrex or silicon.

3. The MEMS pressure sensor of claim 1, wherein the spacer wafer and the micromachined structure are bonded by using one of the following processes: anodic bonding, fusion bonding, glass frit bonding, eutectic bonding, solder preform bonding, and thermo-compressive bonding.

4. The MEMS pressure sensor of claim 1, wherein the cap wafer is coupled to the second surface of the micromachined structure using glass frit bonding, fusion bonding, eutectic bonding, solder preform bonding, flip-chip bonding, or thermo-compressive bonding.

5. The MEMS pressure sensor of claim 1 wherein the etch stopper comprises SiO2 or Nitride.
